(19) United States
(12) Patent Application Publication
(10) Pub. No.: US 2025/0261455 A1
(43) Pub. Date: Aug. 14, 2025

(54) Solar Panel and Photovoltaic Devices having an Integrated Mechanical Protection and Mitigation Layer and having a Cooling Mechanism

(71) Applicant: SOLARPAINT LTD., YOKNEAM ILLIT (IL)

(72) Inventors: Ramon Joseph Albalak, Haifa (IL); Eden Levy, Binyamina (IL)

(21) Appl. No.: 19/180,184

(22) Filed: Apr. 16, 2025

Related U.S. Application Data
(63) Continuation of application No. PCT/IL2023/051106, filed on Oct. 25, 2023.
Application No. PCT/IL2023/051106 is a continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/129,865 is a continuation-in-part of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Dec. 26, 2019.
Application No. PCT/IL2019/051416 is a continuation-in-part of application No. 16/362,665, filed on Mar. 24, 2019, now Pat. No. 11,081,606.
Application No. 18/129,865 is a continuation-in-part of application No. 17/802,335, filed on Aug. 25, 2022, now abandoned.
(60) Provisional application No. 63/381,139, filed on Oct. 27, 2022.
(60) Provisional application No. 63/088,535, filed on Oct. 7, 2020.
(60) Provisional application No. 62/785,282, filed on Dec. 27, 2018.
(60) Provisional application No. 62/785,282, filed on Dec. 27, 2018.
(60) Provisional application No. 62/982,536, filed on Feb. 27, 2020.

(51) Int. Cl. H10F 19/85; H10F 77/63

(52) U.S. Cl. CPC H10F 19/85; H10F 77/68

(57) ABSTRACT

Solar panel and photovoltaic devices having an integrated mechanical protection and mitigation layer and having a cooling mechanism. A photovoltaic device includes, from top to bottom: a top-side encapsulant and top-sheet; beneath them, mechanical resilience and mitigation layer, such as a reservoir storing gel or silicone oil or viscous liquid; beneath it, photovoltaic regions that convert incoming light into electricity; beneath them, a cooling mechanism which runs or traverses within the photovoltaic device, such as water circulating in a set of tubes; beneath it, a bottom-side encapsulant and backsheet. Other types of layers and other orders and arrangements of layers are also disclosed.

### CROSS-REFERENCE TO RELATED APPLICATIONS

This patent application is a Continuation of PCT international application number PCT/IL2023/051106, having an international filing date of Oct. 25, 2023, which is hereby incorporated by reference in its entirety.

The above-mentioned PCT/IL2023/051106 claims priority and benefit from U.S. 63/381,139, filed on Oct. 27, 2022, which is hereby incorporated by reference in its entirety.

The above-mentioned PCT/IL2023/051106 is also a Continuation-in-Part (CIP) of, and claims benefit and/or priority from: U.S. Ser. No. 18/129,865, filed on Apr. 2, 2023, which is hereby incorporated by reference in its entirety.

The above-mentioned U.S. Ser. No. 18/129,865 is a Continuation of PCT international patent application number PCT/IL2021/051202, having an international filing date of Oct. 7, 2021, which is hereby incorporated by reference in its entirety.

The above-mentioned PCT/IL2021/051202 claims priority and benefit: (i) from U.S. 63/088,535, filed on Oct. 7, 2020, which is hereby incorporated by reference in its entirety; and (ii) from U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 18/129,865 is also a Continuation-in-Part (CIP) of U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit: (i) from U.S. Ser. No. 16/362,665, filed on Mar. 24, 2019, now U.S. Pat. No. 11,081,606 (issued on Aug. 3, 2021), which is hereby incorporated by reference in its entirety, and (ii) from U.S. 62/785,282, filed on Dec. 27, 2018, which is hereby incorporated by reference in its entirety.

The above-mentioned U.S. Ser. No. 18/129,865 is also a Continuation-in-Part (CIP) of U.S. Ser. No. 17/802,335 (now having a status of “abandoned”), filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

The above-mentioned PCT/IL2023/051106 is also a Continuation-in-Part (CIP) of, and claims benefit and/or priority from: U.S. Ser. No. 18/372,720, filed on Sep. 26, 2023, which is hereby incorporated by reference in its entirety.

The above-mentioned U.S. Ser. No. 18/372,720 is a Continuation of PCT international application number PCT/IL2022/050339, having an international filing date of Mar. 29, 2022, which is hereby incorporated by reference in its entirety.

The above-mentioned PCT/IL2022/050339 claims priority and benefit from U.S. 63/167,660, filed on Mar. 30, 2021, which is hereby incorporated by reference in its entirety.

The above-mentioned PCT/IL2022/050339 also claims priority and benefit from PCT international application number PCT/IL2021/051202, having an international filing date of Oct. 8, 2021, which is hereby incorporated by reference in its entirety.

The above-mentioned PCT/IL2022/050339 also claims priority and benefit from PCT international application number PCT/IL2021/051269, having an international filing date of Oct. 27, 2021, which is hereby incorporated by reference in its entirety.

The above-mentioned PCT/IL2022/050339 also claims priority and benefit from PCT international application number PCT/IL2022/050030, having an international filing date of Jan. 10, 2022, which is hereby incorporated by reference in its entirety.

The above-mentioned PCT/IL2022/050339 also claims priority and benefit from U.S. Ser. No. 17/353,867, filed on Jun. 22, 2021, now U.S. Pat. No. 11,978,815 (issued on May 7, 2024), which is hereby incorporated by reference in its entirety.

The above-mentioned U.S. Ser. No. 18/372,720 is also a Continuation-in-Part (CIP) of U.S. Ser. No. 18/136,359, filed on Apr. 19, 2023, which is hereby incorporated by reference in its entirety. The above-mentioned U.S. Ser. No. 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from U.S. 63/106,666, filed on Oct. 28, 2020, which is hereby incorporated by reference in its entirety; and also, (ii) from U.S. Ser. No. 17/353,867, filed on Jun. 22, 2021, U.S. Pat. No. 11,978,815 (issued on May 7, 2024), which is hereby incorporated by reference in its entirety.

The above-mentioned U.S. Ser. No. 18/372,720 is also a Continuation-in-Part (CIP) of U.S. Ser. No. 18/217,620, filed on Jul. 3, 2023, which is hereby incorporated by reference in its entirety; which is a Continuation of the above-mentioned PCT international application number PCT/IL2022/050030, having an international filing date of Jan. 10, 2022, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate electricity through the PV effect.

### SUMMARY

Some embodiments provide a solar panel or photovoltaic (PV) device having a mechanical resilience and mitigation layer. For example, a mitigation layer or a reservoir storing a mitigation material (e.g., silicone oil) is located above the active side or the “sunny side” of the PV regions; and protects the PV regions and/or the solar panel from mechanical or functional damage due to hail or branches or debris. Optionally, a mechanical reinforcement layer is located beneath the PV region, for additional mechanical resilience.

Optionally, a Coolant Reservoir is provided as an integral or integrated component of the solar panel or PV device. A coolant flows near or through the solar panel or PV device, and particularly near (or on top of, or beneath) the PV regions. The coolant dissipates or spreads heat, and may circulate via tubes and a pump unit. Optionally, the PV device floats on a body-of-water, and water therefrom is utilized as the coolant to circulate through the tubes and to provide cooling to the PV regions.

In some embodiments, the solar panel is flexible and/or foldable and/or rollable; or at least some of the PV regions are flexible and/or foldable and/or rollable.

Some embodiments provide a solar panel and photovoltaic devices having an integrated mechanical protection and mitigation layer and having a cooling mechanism. For example, a photovoltaic device includes, from top to bottom: a top-side encapsulant and top-sheet; beneath them, mechanical resilience and mitigation layer, such as a reservoir storing gel or silicone oil or viscous liquid; beneath it, photovoltaic regions that convert incoming light into electricity; beneath them, a cooling mechanism which runs or traverses within the photovoltaic device, such as water circulating in a set of tubes; beneath it, a bottom-side encapsulant and backsheet. Other types of layers and other orders and arrangements of layers can be used.

Some embodiments may provide other and/or additional benefits and/or advantages.

### BRIEF DESCRIPTION OF THE DRAWINGS

FIG. 1A is a schematic cross-sectional/side-view illustration of a photovoltaic (PV) device structured as an array or matrix or set of solar cells and having a mitigation/protection layer, in accordance with some demonstrative embodiments.

FIG. 1B is a schematic top-view/upper-side view of a PV device, in accordance with some demonstrative embodiments.

FIG. 2 is a schematic illustration of a cross-sectional side view of a solar panel having a mitigation layer, in accordance with some demonstrative embodiments.

FIG. 3A is a schematic illustration of a cross sectional side view of a solar panel having or incorporating therein an integrated or integral cooling mechanism or temperature-reducing mechanism, in accordance with some demonstrative embodiments.

FIG. 3B is a schematic illustration of a cross sectional side view of another solar panel having or incorporating therein an integrated or integral cooling mechanism or temperature-reducing mechanism, in accordance with some demonstrative embodiments.

FIG. 4 is a schematic illustration of a cross sectional view of a solar cells system incorporating a cooling mechanism or a cooling system, in accordance with some demonstrative embodiments.

FIG. 5 is a schematic illustration of a top view of a solar cells system incorporated with (or having an integral or integrated) cooling system, in accordance with some demonstrative embodiments.

### DETAILED DESCRIPTION OF SOME DEMONSTRATIVE EMBODIMENTS

The Applicant has realized that some conventional solar panels are typically rigid, heavy, cumbersome, brittle and/or fragile units, that are typically installed on roofs or in other locations (e.g., a solar energy park, a solar energy farm, a solar power plant).

Some embodiments provide a solar panel or PV cell, that is mechanically and/or physically and/or functionally protected or enhanced via a mitigation layer and/or a protection layer and/or a cooling layer; as well as flexible and/or rollable (and un-rollable) and/or foldable and/or non-brittle and/or non-fragile solar panels or PV cells that incorporate or include one or more mitigation layer/s and/or protection layer/s and/or cooling layer/s and/or cooling module/s. The flexible solar panel is thus protected from being mechanically/functionally damaged due to heavy rain and/or hail, as well as branches and debris that may be blown with the wind, or against other damage-causing events or harsh weather conditions.

The Applicant has realized that solar panels are often placed outdoors, or on top of roofs or buildings or other structures, or are otherwise exposed to conditions of an outdoor environment that may include harsh weather conditions. The Applicant has also realized that in some situations the surface of a solar panel may become covered by snow or sand, which can be manually removed; however, some weather conditions or events, such as severe rain and/or hail, as well as debris or branches that may be swept or blown by wind, may inflict irreparably damage (e.g., mechanical damage and/or functional damage) upon the solar panel; and may sometimes cause the entire solar panel, or at least regions thereof, to become non-functional or to require partial or full replacement.

The Applicant has realized that the infliction of damage by falling hail or other objects or debris that may fall on the surface of a solar panel, may damage even a generally-flexible solar panel, as it is often not encapsulated within a glass layer or other transparent layer on the “sunny side” (the top side, the active side) of the solar panel that faces outwardly/upwardly towards the environment

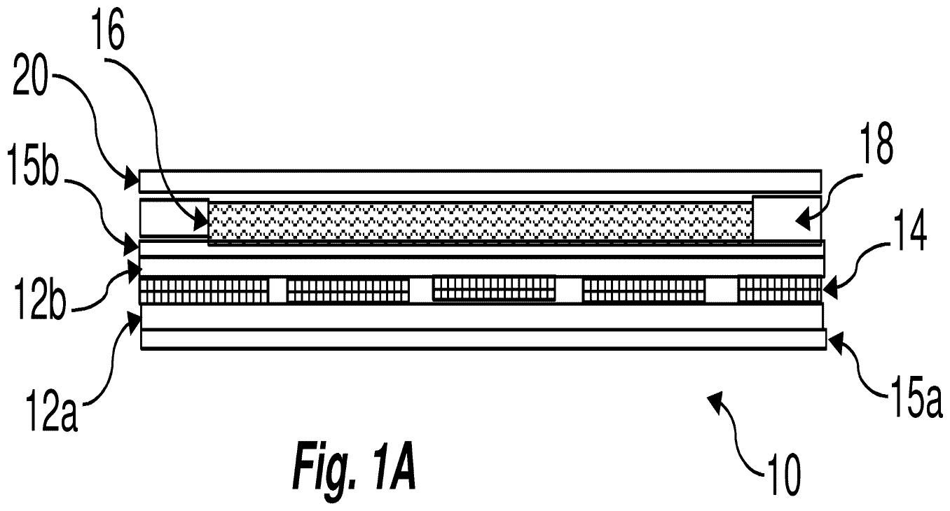

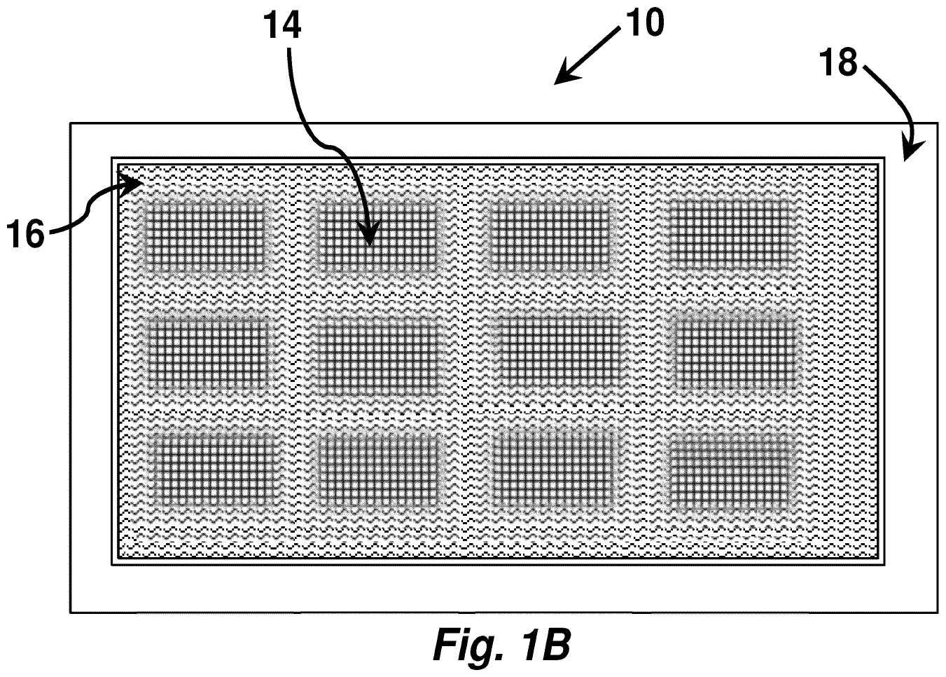

Reference is made to FIG. 1A, which is a schematic cross-sectional/side-view illustration of a photovoltaic (PV) device 10 structured as an array or matrix or set of solar cells and having a mitigation/protection layer, in accordance with some demonstrative embodiments. Reference is also made to FIG. 1B, which is a schematic top-view/upper-side view of that PV device 10, in accordance with some demonstrative embodiments.

For example, a solar panel 10 is shown, optionally implemented as an array or matrix or set of PV regions 14; each PV region 14 may be a separate or autonomous miniature solar cell, or the plurality of PV regions 14 may be a single, singulated/trenched PV cell that has a set or array of non-transcending gaps or craters that penetrate into 51 to 99 percent of a total height of the semiconductor wafer; or may be a flexible thin-film PV cell or a plurality or array or matrix of such PV cells. Solar panel 10 may be implemented as a “mitigated” solar panel, such that it enjoys the advantages of integrated or integral mitigation layer(s)/protection layer(s)/mitigation component(s)/protection component(s).

In the mitigated solar panel 10, the plurality of PV regions 14 may be laminated with or by a bottom-side lamination layer 12a, formed of polyolefin elastomer (POE) or thermoplastic polyolefin (TPO), or Ethylene-Vinyl Acetate (EVA) or as poly(ethylene-vinyl acetate) (PEVA) or other copolymer of ethylene and vinyl acetate, or a combination of two or more of such materials, or a combination of POE and/or TPO and/or EVA and/or PEVA and/or other lamination material(s) and/or other polymers and/or other elastomers.

Similarly, the plurality of PV regions 14 may be laminated with or by an upper-side lamination layer 12b, formed of polyolefin elastomer (POE) or thermoplastic polyolefin (TPO), or Ethylene-Vinyl Acetate (EVA) or as poly(ethylene-vinyl acetate) (PEVA) or other copolymer of ethylene and vinyl acetate, or a combination of two or more of such materials, or a combination of POE and/or TPO and/or EVA and/or PEVA and/or other lamination material(s) and/or other polymers and/or other elastomers.

Additionally or alternatively, mitigated solar panel 10 may further include at least one outer back layer 15a; for example, formed of polyvinylidene fluoride (PVDF), Ethylene tetrafluoroethylene (ETFE) or fluorine-based plastic, Ethylene-Chlorotrifluoroethylene (ECTFE) or other alternating copolymer of ethylene and chlorotrifluoroethylene or a semi-crystalline fluoropolymer or a partly fluorinated polymer), Polyethylene Terephthalate (PET) or other thermoplastic polymer or thermoplastic polymer resin, or a combination of two or more of the above materials and/or other lamination/encapsulation material(s) and/or other polymers and/or other elastomers.

Mitigated solar panel 10 may further include at least one outer front layer 15b; for example, formed of polyvinylidene fluoride (PVDF), Ethylene tetrafluoroethylene (ETFE) or fluorine-based plastic, Ethylene-Chlorotrifluoroethylene (ECTFE) or other alternating copolymer of ethylene and chlorotrifluoroethylene or a semi-crystalline fluoropolymer or a partly fluorinated polymer), Polyethylene Terephthalate (PET) or other thermoplastic polymer or thermoplastic polymer resin, or a combination of two or more of the above materials and/or other lamination/encapsulation material(s) and/or other polymers and/or other elastomers.

In some embodiments, a top-side of the PV regions 14 is laminated/encapsulated by a first set of layers, which may include one or more layers; and a bottom-side of the PV regions 14 is similarly laminated/encapsulated by a second set of layers, which may include one or more layers. In some embodiments, the first set of layers has the same number of layers as the second set of layers; whereas, in other embodiments, the first set of layers has a first number of layers, whereas the second set of layers has a second, different, number of layers. In some embodiments, the type of layers of the first set, may be identical to the type of layers of the second set; whereas, in other embodiments, the first set of layers and the second set of layers may be non-identical and may include different types of layers, such that the first set includes at least one layer that is not included in the second set, and/or such that the second set includes at least one layer that is not included in the first set. Similarly, the thickness or height or depth of each layer may vary between the first set and the second set. A particular combination of upper-side lamination/encapsulation layers and bottom-side lamination/encapsulation layers may be configured and structured in order to provide a particular functionality; for example, increased or reduced flexibility/rigidity, increased or reduced mechanical resilience, increased or reduced thermal resilience, or other functional goals.

In accordance with some embodiments, on top of the layer of PV regions 14, and the two upper-side lamination/encapsulation layers 12b and 15b, there is provided a reservoir of liquid 16. The liquid can be, for example, a viscous liquid or a relatively viscous liquid (e.g., having viscosity greater than a pre-defined threshold value); and/or a liquid having a refraction index that is similar to (or very close to) the refraction index of the surrounding layers such that light photons can easily reach the PV regions 14 that are located beneath the liquid. An example for such a liquid is silicone oil, that does not distract or obstruct the light passing through, and can be used to form an efficient mitigation layer. In some embodiments, other liquids or fluids or materials may be used; for example, silicone oil, vegetable oil, glycerin or glycerine or glycerol, translucent motor oil, a clear or colorless or transparent or translucent polyol compound and/or viscous polyol compound, propane derivative(s), and/or a combination or mixture of two or more of these materials and/or other materials. In some embodiments, the liquid or viscous liquid is particularly selected to be generally non-flammable, to prevent flaming of the liquid or nearby components if the solar panel heats up to a pre-defined threshold temperature.

In some embodiments, the liquid that is utilized in (or as) the mechanical mitigation and resilience layer, is a liquid having viscosity in the range of 1 to 999 centipoise; or in the range of 2 to 999 centipoise; or in the range of 5 to 999 centipoise; or in the range of 1 to 800 centipoise; or in the range of 2 to 800 centipoise; or in the range of 5 to 800 centipoise; or in the range of 1 to 500 centipoise; or in the range of 2 to 500 centipoise; or in the range of 5 to 500 centipoise; or in the range of 1 to 250 centipoise; or in the range of 2 to 250 centipoise; or in the range of 5 to 250 centipoise; or in the range of 1 to 100 centipoise; or in the range of 2 to 100 centipoise; or in the range of 5 to 100 centipoise; or in the range of 1 to 50 centipoise; or in the range of 2 to 50 centipoise; or in the range of 5 to 50 centipoise; or in the range of 500 to 999 centipoise; or in the range of 250 to 999 centipoise; or in the range of 100 to 900 centipoise; or in the range of 5 to 999 centipoise; or in the range of 5 to 500 centipoise; or in the range of 5 to 250 centipoise; or in the range of 100 to 750 centipoise; or below 900 centipoise; or above 2 centipoise; or above 5 centipoise; or above 10 centipoise; or above 20 centipoise; or above 50 centipoise; or above 100 centipoise; or above 200 centipoise; or above 500 centipoise; wherein the above are measured at 25 degrees Celsius, as absolute viscosity or as dynamic viscosity or as kinematic viscosity; wherein 1 centipoise is 0.1 Pascal x Second. Other suitable values or ranges-of-values can be used, to provide a desired level of mechanical resilience and mitigation characteristics.

In some embodiments, the liquid utilized in or as mechanical mitigation and resilience layer may be transparent or partially-transparent or mostly-transparent or semi-transparent; or may be translucent or partially-translucent or mostly-translucent or semi-translucent; or may allow passage therethrough of at least 51 percent of incoming light; or may allow passage therethrough of at least 67 percent of incoming light; or may allow passage therethrough of at least 75 percent of incoming light; or may allow passage therethrough of at least 80 percent of incoming light; or may allow passage therethrough of at least 90 percent of incoming light; or may allow passage therethrough of at least 95 percent of incoming light; or may allow passage therethrough of at least 99 percent of incoming light.

In some embodiments, optionally, the liquid reservoir 16 is also covered with or by a layer 20 of polyvinylidene fluoride (PVDF), or ETFE, or ECTFE, or PET, or other suitable materials, or a combination thereof.

In some embodiments, the liquid reservoir 16 is confined or constrained from one or more of its sides by an enclosing rim 18; which may be formed of POE or TPU or EVA or PEVA or one or more materials similar to those of layers 12a or 12b or 15a or 15b or 20.

In accordance with some embodiments, the liquid reservoir 16 is confined and can be injected or inserted or added or glued or bonded or “sandwiched” between the layers as depicted, in order to protect the PV regions 14 and/or to mitigate a possible damage from objects or debris that may otherwise inflict damage directly onto the PV regions 14. cells. Other methods of introducing the liquid to between the layers can be used without limiting the scope of the present subject matter.

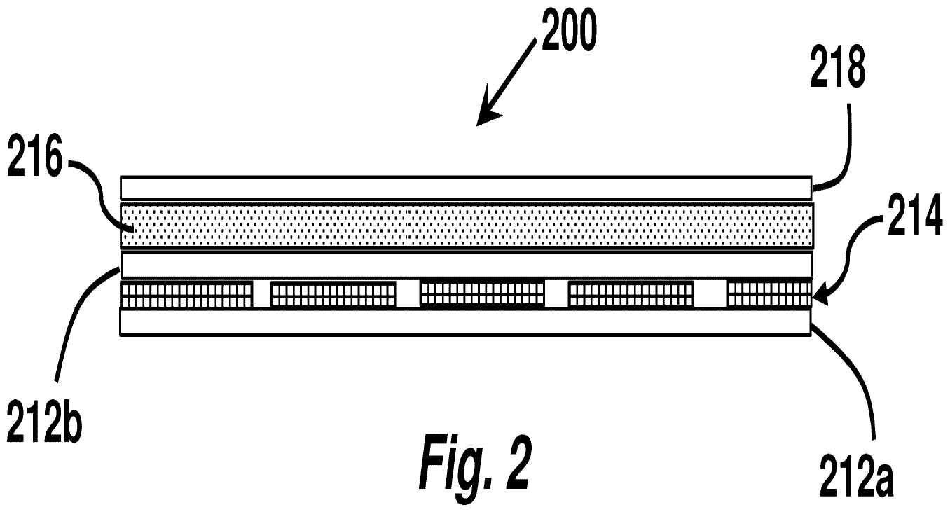

Reference is made to FIG. 2, which is a schematic illustration of a cross-sectional side view of a solar panel 200 having a mitigation layer, in accordance with some demonstrative embodiments.

For example, mitigated solar panel 200 includes a plurality of PV regions 214 (e.g., similar to PV regions 14 described above); which may be laminated/encapsulated with a bottom-side lamination layer 212a and/or a top-side lamination layer 212b, formed of an encapsulating material such as POE and/or TPU and/or EVA and/or PEVA. Optionally, a back-sheet and/or a top-sheet may further be laminated or encapsulated, similar to layers 15a and 15b discussed above, as an outer back layer and an outer front layer; such as, formed of PVDF or ETFE or ECTFE or PET or a combination of such materials or other suitable material(s). In order to not over-crowd the drawing, FIG. 2 shows component 212a as representing all such bottom-side lamination layer(s) and/or bottom-side encapsulation layer(s) and/or bottom-side back-sheet; and similarly, shows component 212b as representing all such top-side lamination layer(s) and/or top-side encapsulation layer(s) and/or top-side top-sheet.

In accordance with some embodiments, on top of the layer of PV regions 214, there is provided a protective layer 116 formed of (for example,) gel or gel-like material, or a thick or relatively-thick gel-like material. The gel-like layer material can be epoxy, a derivative of epoxy, a viscous solution, a viscous liquid, a partially crosslinked polymer, a natural polymer, a swollen polymer, a combination of two or more such materials, and/or other suitable material(s). A functional characteristic of the gel-like protective layer 116 is that it has a refraction index that is similar to (or very close) to the refraction index of the surrounding layers, such that light photons can easily reach the PV regions 214 are located beneath the protective layer 216.

In a non-limiting demonstrative experiment, the mitigation/protection layer(s) described above and/or herein were tested, and demonstrated efficient/effective protection or mitigation against dropped beads that were dropped, simulating hail or simulating falling debris. The weight of the each bead was about 0.42 gram; the beads were dropped from a height of about 2 meters onto the solar panel incorporating such mitigation/protection layers. Such simulated hail tests has demonstrated significantly reduced damage in electroluminescence images, and a significantly smaller reduction in efficiency for solar panels that included such mitigation/protection layer.

Additionally or alternatively, one or more mechanical reinforcement layers (e.g., made of glass fibers or fiber-glass) may be provided at (or glued or bonded beneath) the bottom side of the solar panel (100 or 200) and/or beneath the PV regions (14 or 214), beneath the solar cells. Additionally or alternatively, one or more layers of soft, impact-absorbing, materials (e.g., POE and/or TPU) may be placed or bonded or glued above or over the solar panel (100 or 200) and/or over the PV regions (14 of 214), to increase hail resistance and/or mechanical resilience.

In accordance with some other experimental tests and simulated hail tests, the Applicant has realized that incorporating a mitigation layer at the front side (the top side, the “sunny side”, the active side) and also hardening or providing reinforced layer(s) beneath the PV regions/the solar panel, may provide maximal protection and mechanical resilience to the solar panel.

The Applicant has further realized that solar panels and PV devices are often exposed outdoors, or are located or placed in an outdoor environment, and are typically operable in conditions of direct sunlight or other light. The Applicant has realized that an increase in temperature of the solar panel, due to direct sunlight and/or ambient conditions (e.g., being placed in a generally hot geographical area, or due to hot weather, or a hot climate) and/or due to the photovoltaic activity itself (conversion of light into electric energy), may reduce the efficiency of a solar cell or solar panel or PV device.

The Applicant has realized that cooling or reducing the temperature of the solar panel or PV device may be required or may be advantageous in order to maintain its operational efficiency, or to prevent or reduce a possible reduction in efficiency due to heating.

The Applicant has realized that some conventional systems attempt to cool-down solar panels by watering the solar panels with water sprinklers, to provide water that flows onto the front surface of the solar panel. However, realized the Applicant, such conventional systems are not environmentally friendly, and may require utilization or wasting of large volumes of waters; and/or may involve increased costs for the water being sprayed and for the sprinkler system that sprays it; and/or may require the installation and maintenance of a sprinklers system; and/or may be non-feasible or impossible in some particular installations of solar panels, such as in locations that do not have an available connection to a water system.

The Applicant has realized that there is a need to provide an efficient solution for a cooling mechanism that preferably provides constant cooling to solar panels and PV devices. Moreover, realized the Applicant, there is a need to provide a cooling system that can be selectively or dynamically controlled according to the temperature to which the solar panels are actually exposed and/or the temperature to which the solar panels are actually exposed.

Some embodiments thus provide a solar panel or PV device (and particularly, a flexible and/or foldable and/or rollable and/or mechanically resilient and/or non-brittle solar panel) that incorporates therein an integrated or integral cooling system or cooling component or cooling mechanism, or a self-cooling solar panel or PV device, or an autonomously-cooling solar panel or PV device. In some embodiments, the innovative cooling mechanism may dynamically control and/or modify and/or reduce the temperature of the solar panel or PV device, taking into account the surrounding/ambient temperature or weather and/or the current/actual/dynamically-changing temperature of the solar panel itself.

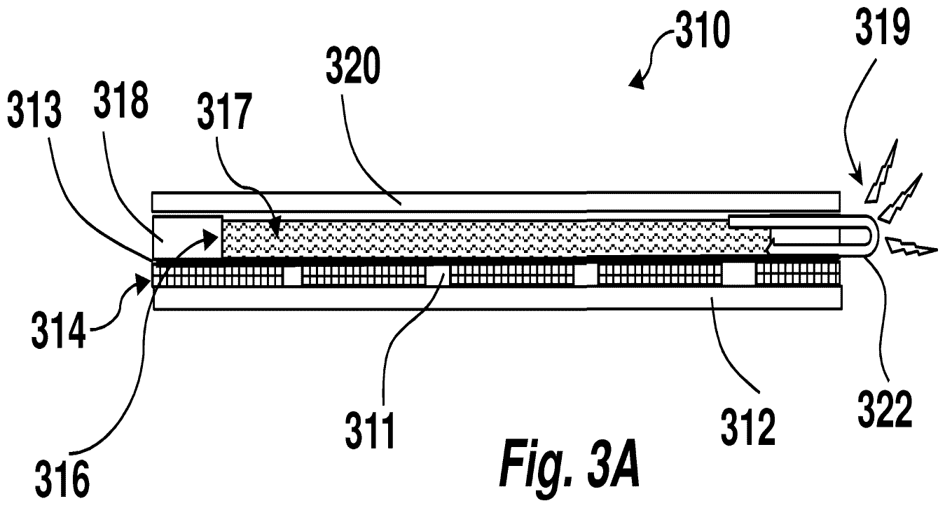

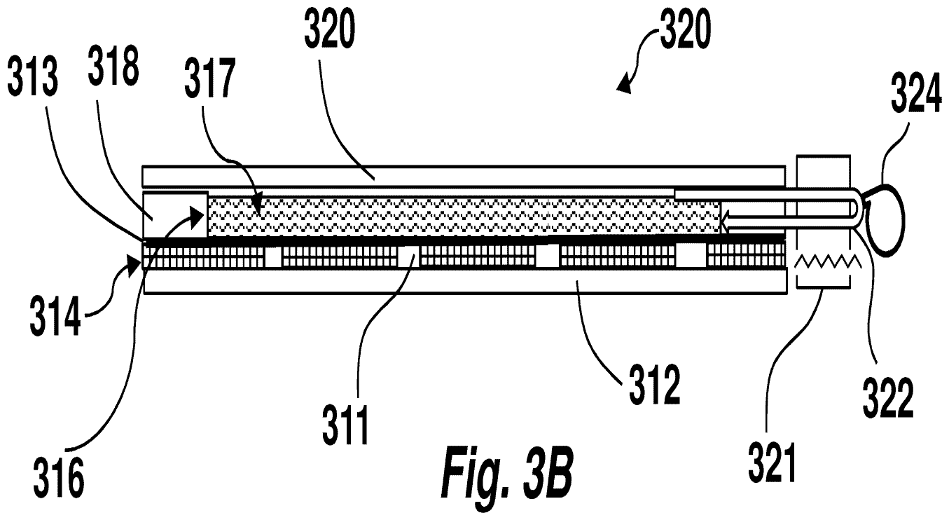

Reference is made to FIG. 3A, which is a schematic illustration of a cross sectional side view of a solar panel 310 having or incorporating therein an integrated or integral cooling mechanism or temperature-reducing mechanism, in accordance with some demonstrative embodiments.

For example, solar panel 310 comprises a plurality of solar cells or PV regions 314 which may be arranged in an array or matrix or group or set. The set or array of PV regions 314 may be laminated and/or encapsulated with (or by) an encapsulant 311, for example, formed of POE and/or TPU and/or EVA and/or PEVA, or a combination of two or more of these materials, or other suitable polymers or elastomers or other material(s).

Solar panel 310 may further comprise outer back layer(s) 312 and/or outer top layer(s) 313, which may be formed of PVDF and/or ETFE and/or ECTFE and/or PET, or a combination of two or more of these materials, or other suitable polymers or elastomers or other material(s).

In some embodiments, the active side or the “sunny side” or the top side of solar panel 310, which is intended to directly face or directly receive the incoming sunlight or light, may have a first set of lamination/encapsulation layers; and the other side or the opposite side or the “dark side” or the bottom side of solar panel 310 may have a second set of lamination/encapsulation layers, which may be identical or may be different in the number of layers, the type of layers, the thickness/depth/height of layers, the materials from which layers are formed, the order or arrangement of layers, and/or other characteristics.

In some embodiments, PV regions 314 are rigid or generally-rigid or non-flexible or non-rollable PV regions or solar cells. In other embodiments, PV regions 314, or at least some of them, are flexible and/or rollable (and unrollable) and/or foldable (and un-foldable) and/or non-brittle PV regions or solar cells; for example, the plurality of PV regions 314 may be a single, singulated/trenched PV cell that has a set or array of non-transcending gaps or craters that penetrate into 51 to 99 percent of a total height of the semiconductor wafer; or may be a flexible thin-film PV cell or a plurality or array or matrix of such PV cells.

On top of the layer of PV regions 314, the encapsulant layer(s) 311, and preferably on top of the upper top layer(s) 313 or top-sheet, there is provided an innovative Coolant Reservoir 316, storing a coolant 317; such that the Coolant Reservoir 316 and/or the Coolant 317 is (or are) in thermal contact with the PV regions 314 and/or such that the coolant reservoir 316 and/or the coolant 317 is (or are) in sufficient proximity to PV regions 314 to thermally affect them and/or to reduce the temperature of PV regions 314.

In some embodiments, coolant 317 is entirely trapped within the coolant reservoir 316 which is a closed channel or a closed pocket or a closed container; such that the coolant 317 itself does not directly touch the PV regions 314; yet the coolant 317 is in sufficient proximity (e.g., under 1 millimeter, under 2 millimeters) relative to the PV regions 314 such that the coolant 317 can still cool them down or reduce their temperature.

In other embodiments, the coolant 317 itself may be in a direct physical contact with the PV regions 314. In such implementations, the coolant is an electrically non-conducting material.

In some embodiments, the coolant 17 is circulated within the coolant reservoir 316, and can be a fluid or a liquid (or a combination or mixture of liquids) that acts as a heat dissipator or a heat spreader. In some embodiments, the coolant liquid has a refraction index that is similar to (or very close to) the refraction index of the surrounding layers, so that light photons can easily reach the PV regions that are located beneath the coolant liquid. In some embodiments, the coolant 317 may be or may include: water; cooled air, chilled air; or other material that does not distract or obstruct the light passing through it.

In some embodiments, the coolant 317 is a liquid having low viscosity or having high fluidity; such as water, or having viscosity (or fluidity) close or similar to water; in order to enable passage of light through such liquid (e.g., since high viscosity liquids are often non-transparent, or are less translucent than low viscosity liquids), and/or in order to require reduced power or reduced pumping forces in order to circulate/pump such liquid. In some embodiments, such coolant 317 may have viscosity of 1 centipoise, or in the range of 1 to 5 centipoise, or in the range of 1 to 10 centipoise, or in the range of 0.50 to 5 centipoise, or in the range of 0.5 to 10 centipoise, or in the range of 0.5 to 1.5 centipoise, or in the range of 0.5 to 20 centipoise; wherein the above are measured at 25 degrees Celsius, as absolute viscosity or as dynamic viscosity or as kinematic viscosity; wherein 1 centipoise is 0.1 Pascal x Second. Other suitable values or ranges-of-values can be used, to provide a desired level of fluidity that enables efficient circulating/pumping of the coolant through the tubes system.

In some embodiments, the coolant may be transparent or partially-transparent or mostly-transparent or semi-transparent; or may be translucent or partially-translucent or mostly-translucent or semi-translucent; or may allow passage therethrough of at least 51 percent of incoming light; or may allow passage therethrough of at least 67 percent of incoming light; or may allow passage therethrough of at least 75 percent of incoming light; or may allow passage therethrough of at least 80 percent of incoming light; or may allow passage therethrough of at least 90 percent of incoming light; or may allow passage therethrough of at least 95 percent of incoming light; or may allow passage therethrough of at least 99 percent of incoming light.

In some embodiments, optionally, additionally or alternatively, coolant reservoir 316 can be positioned or located or structured between the polymeric layers used in manufacturing the solar panel, and/or beneath one or more of the layers of the solar panel, and/or beneath the bottom side of the PV regions 314, and/or beneath the lamination/encapsulation layers that are beneath the PV regions 314; or, the coolant reservoir 316 may be “sandwiched” or trapped as an inner layer or inner component among the several layers of the solar panel 310.

In some embodiments, the liquid reservoir 316 is confined or constrained from one or more of its sides by an enclosing rim 318; which may be formed of POE or TPU or EVA or PEVA or one or more materials similar to those of layers 12a or 12b or 15a or 15b or 20 described above, and/or may be formed of polymeric material or a silicone-based material or other sealant(s). In some embodiments, the coolant reservoir 316 or the coolant 317 itself is confined by PVDF and/or ETFE and/or ECTFE and/or PET, or a combination of two or more of these materials and/or other material(s); such as being confined by a first layer from its upper side and a second layer from its lower side and/or by the enclosing rim 318 from its other sides.

In some embodiments, optionally, additionally or alternatively, a tube 322 may be provided, through which the coolant 317 can circulate to outside the coolant reservoir 316 and re-enter again (e.g., in a closed loop or in a recycling loop; or, in some implementations, in an open loop or an open flow) while dissipating or spreading or carrying-away the heat that is transferred from the heated PV regions 314 to the coolant 317. The circulation of the coolant fluid can be performed through a pump or a pumping unit or suction unit or a pressure generating unit, that can be positioned outside the coolant reservoir and/or outside the solar panel 310 itself, in the area of the outer tube 322. The length of the tube 322 can be configured such that the coolant 317 within the tube is cooled when it is circulated outside of the solar panel 310 and reaches the desired coolant temperature before re-entering the coolant reservoir 316. The coolant 317 may be cooled by convection during its passage through the outer tube 322, as indicated by arrow 319 demonstrating the cooling down or the temperature reduction or the heat dissipation or the heat spreading via the passage of the tube and the coolant externally to the solar panel 310 and/or away from the PV regions 314.

In some embodiments, solar panel 310 may float on water or may be self-floating or self-buoyant; and tube 322 may be in thermal contact with (or surrounded by, or dipped entirely in, or dipped at least partially in) the body of water (e.g., lake, pool, ocean) upon which the solar panel is floating for the purpose of heat exchange and/or heat dissipation.

Reference is made to FIG. 3B, which is a schematic illustration of a cross sectional side view of another solar panel 320 having or incorporating therein an integrated or integral cooling mechanism or temperature-reducing mechanism, in accordance with some demonstrative embodiments.

Solar panel 320 may be generally similar to solar panel 310 describe above; however, in solar panel 320, optionally and/or depending on the temperature range that the solar panel 320 or the PV regions 314 reach, and/or depending on the geographical region or spatial location in which the solar panel 320 is deployed, there is provided an optional heat exchanging unit 321 or a cooling unit or a cool-air blowing unit or a cool-air generating unit (e.g., which may utilize electric and/or chemical heat exchange); such as, in proximity to or or surrounding or enveloping or even in contact with the tube 322. Accordingly, heat from the coolant liquid that is getting out of the fluid reservoir 316 is dissipated or spread to the coolant liquid that passes through or near the heat exchanging unit 321 and is cooled before it re-enters the fluid reservoir 316. Optionally, a pump 324 or a suction mechanism or a material-pulling mechanism or a fluid-circulating unit or a liquid-circulating unit is provided, in order to circulate the coolant fluid in the tube 322. In some embodiments, tube 322 or portions thereof can pass through dedicated holes or apertures or tunnels in the rim 318, to enable fluid communication between the fluid reservoir 316 and the outer environment, so that the fluid can be cooled again before re-entering the fluid reservoir 316. Additionally or alternatively, the communication between the coolant reservoir 316 and the tube 322 or the heat exchange unit 321 in which (or, near which) the coolant fluid 317 from the coolant reservoir is dissipating the heat from the solar panel 320 or from its PV regions 314, can be implemented through or via or in proximity to other and/or additional regions or layers or components of solar panel 320, and not necessarily through or near the rim 318 of the enclosure.

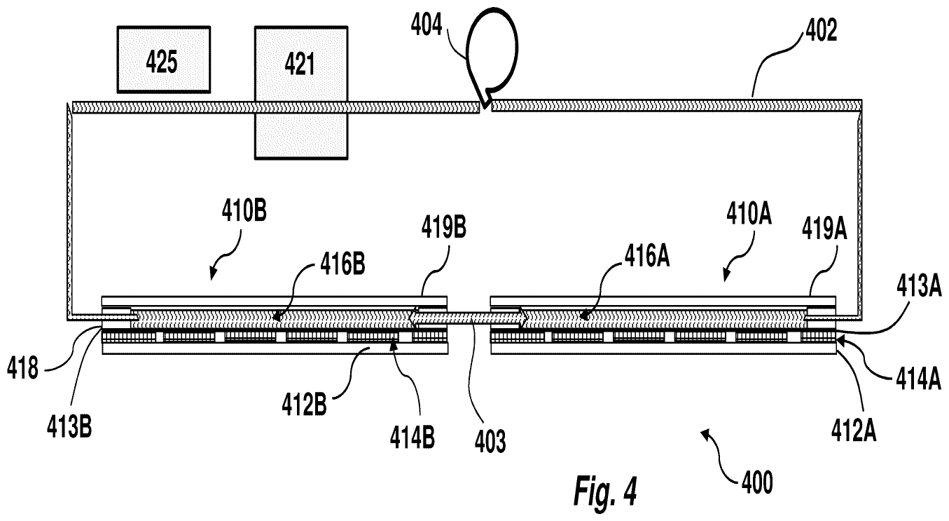

Reference is made to FIG. 4, which is a schematic illustration of a cross sectional view of a solar cells system 400 incorporating (or incorporated with) a cooling mechanism or a cooling system, in accordance with some demonstrative embodiments.

For example, solar cells system 400 comprises a plurality of solar panels (e.g., optionally, flexible and rollable solar panels); for demonstrative purposes and in order to avoid over-crowding of the drawings, only two such solar panels are shown (denoted 410A and 410B); although some implementations may similar co-locate dozens or even hundreds of such solar panels in a single solar cells system 400.

Each solar panel (410A, 410B) comprises an encapsulated solar cells layer or PV regions layer (414A, 414B); and optionally also bottom-side lamination/encapsulation layer(s) (412A, 412B); and optionally also top-side lamination/encapsulation layer(s) (413A, 413B), such as formed of PVDF, or ETFE, or ECTFE, or PET, or a combination thereof, and/or other materials).

Each solar panel (410A, 410B) has its own upper-side (active side, “sunny side”) Coolant Reservoir (416A, 416B), storing therein Coolant 417 in liquid or fluid or gas phase. Optionally, each such Coolant Reservoir (416A, 416B) may be enclosed at its side(s) by a rim (418A, 418B). On top of each Coolant Reservoir (416A, 416B) there is an encapsulation/lamination layer (419A, 419B); for example, formed of PVDF and/or ETFE and/or ECTFE and/or PET and/or other material(s).

A set or an arrangement of one or more tubes 402 is provided, for fluidically connecting the plurality of Coolant Reservoirs (416A, 416B) of the respective plurality of solar panels (410A, 410B); such that the same Coolant 417 is circulating within the set of tubes 402 and the plurality of Coolant Reservoirs (416A, 416B); optionally utilizing a single pump 404 or a plurality of pumps for assisting in such circulation via generation of pumping force. Tube-portion 403 demonstrates a portion or region of the set of tubes 403, which directly inter-connects two neighboring (yet generally separate) Coolant Reservoirs (416A, 416B).

In some embodiments, optionally, one or more heat exchange units may further be provided, surrounding or enveloping tubes 402 or being in contact with tubes 402 or being in proximity to tubes 402; such that the coolant fluid 417 that passes through tubes 402 is cooled down while dissipating or spreading the heat that is withdrawn from the solar panels (410A, 410B) and/or from the PV regions (314A, 314B) while the fluid passes through the Coolant Reservoirs (416A, 416B). For demonstrative purposes, there is shown a first heat exchange unit 421 (or cooling unit, or temperature reduction unit), which surrounds or envelopes a portion of a tube of the set of tubes 402, such that this tube-portion passes through or within the first heat exchange unit 421. Additionally or alternatively, there is shown a second heat exchange unit 425 (or cooling unit, or temperature reduction unit), which does not surround the tube(s) 402 but rather is positioned in spatial proximity (e.g., 1 or 2 millimeters away from) and/or in direct contact with a portion of a tube of the set of tubes 402, such that this tube-portion passes near the second heat exchange unit 425. Other possible placement arrangements may be used.

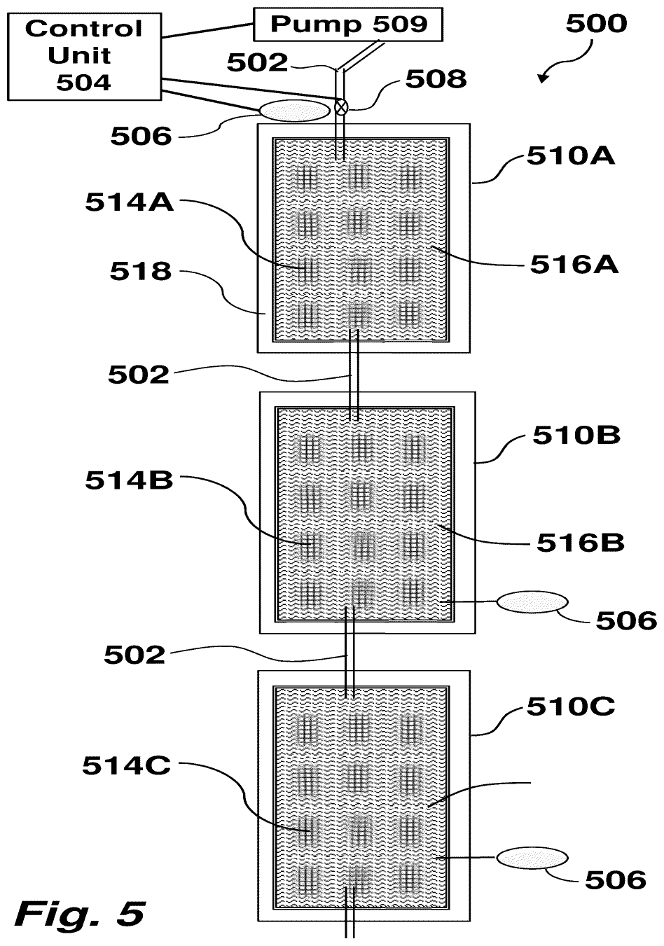

Reference is made to FIG. 5, which is a schematic illustration of a top view of a solar cells system 500 incorporated with (or having an integral or integrated) cooling system, in accordance with some demonstrative embodiments.

A plurality of solar panels or solar cells are inter-connected; for demonstrative purposes, three such solar panels are shown, denoted 510A and 510B and 510C; although in some implementations, dozens or even hundreds of such solar panels may be inter-connected in a single solar cell system 500.

Each solar panel (510A, 510B, 510C) has a plurality of PV regions (denoted 514A, 514B, 514C); and has its own Coolant Reservoir (denoted 516A, 516B, 516C) that is positioned in proximity to (or touching) the respective layer of PV region (514A, 514B, 514C). The coolant reservoirs may be enclosed within an enclosing rim 518 or other bordering element or margin-creating element or divider or frame. The coolant reservoirs (516A, 516B, 516C) are fluidically inter-connected through a set of 502, through which the coolant passes or flows or circulates.

Additionally or alternatively, solar cells system 500 may be placed or may float on top of a body-of-water (e.g., lake, pool, sea, ocean, water reservoir); and the coolant that is used for flowing through the coolant reservoirs (516A, 516B, 516C) can be the surrounding water from the body-of-water itself. For example, water from the body-of-water or the water reservoir can be pumped via a pump into the set of tubes 502 via a water inlet at a first side of the solar cells system 500, and can be returned to the water reservoir as they exit from an will be returned to the reservoir through a water outlet at a second side of the solar cells system 500; without necessarily utilizing or performing an entire closed-loop circulation, but rather using an open-loop circulation in which water from the reservoir flow through the tubes 302. In such implementations, and particularly if the water reservoir is large (e.g., a lake), it may be possible to avoid the user of a heat exchange unit, since the sufficiently-large water reservoir may be sufficient for dissipating/spreading/exchanging the heat that is generated by or that is captured from the solar cells system 500 and/or from its PV regions.

Additionally and alternatively, the temperature of the solar cells and/or the temperature of the coolant fluid in the tubes, may be controlled or modified through a control unit 504; which may be configured or programmed to control or to modify, for example, the flow rate of the coolant fluid in the tubes according to temperature measurements taken from temperature sensors 506 or thermometers that are positioned adjacent to (or mounted on or under or next to) the solar cells and/or the tubes, before entering the tubes and/or at their inlet. The control unit 504 may be connected via wired or wireless link to the sensors 506, as well as to one or more flow valves 508 located in the tubes or adjacent to the pump 509.

### Additional/Optional Features

In some embodiments, a solar cell or solar panel or PV device that is utilized may be an autonomously flexible and/or rollable and/or foldable solar cell, that does not break and does not brittle when flexed or curved or bent or folded or rolled, and that is resilient to mechanical forces, and that can autonomously absorb and/or dissipate and/or withstand mechanical forces and mechanical shocks; for example, by being singulated or segmented or grooved or trenched with non-transcending gaps or “blind gaps” or craters or grooves or trenches, that penetrate some-but not all-of the thickness (or the depth) of a silicon layer or a semiconductor body or a semiconductor wafer; and optionally by having filler material(s) in such grooves or trenches or non-transcending gaps or non-transcending craters, to further absorb and/or dissipate mechanical forces and shocks.

Optionally, some embodiments may be utilized in conjunction with PV devices and/or solar panels and/or components and/or methods that are described in U.S. Pat. No. 11,081,606, titled “Flexible and rollable photovoltaic cell having enhanced properties of mechanical impact absorption”, which is hereby incorporated by reference in its entirety; and/or in conjunction with components, structures, devices, methods, systems and/or techniques that are described in patent application number U.S. Ser. No. 17/353,867, filed on Jun. 22, 2021, published as US 2021/0313478 A1, which is hereby incorporated by reference in its entirety; and/or with solar panels or solar cells or PV devices that are singulated or segmented or trenched or grooved, or that are flexible and/or rollable and/or foldable, and/or that include “blind gaps” or non-transcending gaps or craters. Some embodiments may provide a flexible and rollable PV cell or solar cell; wherein a silicon body or semiconductor body or semiconductor substrate or semiconductor wafer has non-transcending craters or “blind gaps” that penetrate into between 75 percent and 99 percent of a total thickness of the semiconductor body (or wafer, or substrate), and that do not penetrate into an entirety of the total thickness of the semiconductor body (or wafer, or substrate); wherein said non-transcending craters or “blind gaps” increase flexibility/or and mechanical resilience and/or mechanical shock absorption of the PV cell. In some embodiments, some, or most, or all of the non-transcending craters or “blind gaps” contain a filler material having mechanical force absorption properties, which provides mechanical shock absorption properties and/or mechanical force dissipation properties to the PV cell.

In some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film.

In some embodiments, each single solar cell that is flexible and rollable by itself, is not a collection and is not an arrangement and is not an assembly of multiple discrete solar cells of PV modules, that each one of them has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrode arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

For demonstrative purposes, some portions of the discussion relate to utilization of the flexible polyimide film (or strips, or bands, or straps, or surfaces) as part of a stand-alone solar panel or as part of a vehicular component or a vehicle; however, some embodiments may similarly provide a solution that can be utilized with, or in, or in conjunction with, other objects or articles or structures; for example, a roof, a roof shingle, a wall, a panel, a side-panel, a horizontal panel, a vertical panel, a slanted panel, an aircraft part, an aircraft, a drone part, a drone, a spacecraft part, a spacecraft, a marine vessel part, a marine vessel, a boat, a ship, a yacht, a floating device, a swimming pool cover or a lake cover, a submarine vessel part, a submarine vessel, a construction equipment or vehicle or agricultural machinery (e.g., bulldozer, tractor, harvester, cotton collector, crane), a bus-stop roof or structure, a gazebo roof, a patio roof, an awning, a greenhouse, a parking spot cover or a parking lot cover, a playground cover, a stadium cover or roof, a shed or a toolshed, a road divider, a road sign, a billboard, a shipping container (e.g., enabling the integration of the solar panel in a roof or side-panel of a shipping container, to provide electric power to electric devices within the container and/or to cooling systems or fans that can cool or can reduce the temperature of top-layer containers on ships), and/or other suitable objects or structures.

The term “vehicle” as used herein may comprise, for example, a car, a sedan car, a sport utility vehicle (SUV), a truck, a bus, a van, a minivan, a train, a wagon of a train, a car of a train, a military vehicle (e.g., a tank, an armored fighting vehicle (AFV), a combat vehicle, or the like), a first responder or law enforcement vehicle (e.g., police car, ambulance, firetruck), a cargo vehicle, a trailer, a mini-trailer, a vehicle for transporting persons and/or animals and/or other cargo, an agricultural vehicle or mobile agricultural equipment (e.g., a tractor, a combine harvester, a cotton harvester, a harvester, a crop sprayer, a hay baler, or the like), a vehicle having a generally flat roof, a vehicle having a curved roof, an autonomous car or vehicle, a self-driving car or vehicle, a remote-controlled car or vehicle, a remotely-controlled car or vehicle, an Electric Vehicle (EV), an Electric Utility Vehicle (EUV), an Internal Combustion Engine (ICE) vehicle or a gasoline vehicle that utilizes the solar panel to recharge its battery and/or to provide power to devices within the vehicle, a hybrid vehicle, or the like.

Some embodiments provide a photovoltaic (PV) device, comprising: a plurality of PV regions, configured to generate electricity from incoming light; wherein the PV regions have: a top-side that is intended to face the incoming light, and a bottom-side that is opposite to said top-side; and a mechanical resilience and mitigation layer, located above the top-side of the PV regions, configured to protect the PV regions from mechanical and functional damage by hail and debris.

In some embodiments, the mechanical resilience and mitigation layer comprises a reservoir that contains a liquid. In some embodiments, wherein the mechanical resilience and mitigation layer comprises a reservoir that contains a viscous liquid. In some embodiments, the mechanical resilience and mitigation layer comprises a reservoir that contains a viscous liquid that is transparent.

In some embodiments, the mechanical resilience and mitigation layer comprises a reservoir that contains a viscous liquid (I) that is translucent and enables passage therethrough of at least 75 percent of incoming light, and (II) that has viscosity in a range of 2 to 999 centipoise.

In some embodiments, the mechanical resilience and mitigation layer comprises a reservoir that contains oil and/or gel. In some embodiments, the mechanical resilience and mitigation layer comprises a reservoir that contains silicone oil. In some embodiments, the reservoir is enclosed within an enclosing rim that forms a frame separating the reservoir and the PV regions.

In some embodiments, the mechanical resilience and mitigation layer is not stored within a constraining reservoir, but rather, the mechanical resilience and mitigation layer comprises a gel that is surrounding or covering or coating at least the top-side of the PV regions.

In some embodiments, the mechanical resilience and mitigation layer is not stored within a constraining reservoir. Rather, for example, the mechanical resilience and mitigation layer comprises a partially cross-linked polymer (and/or gel) that is surrounding or covering or coating at least the top-side of the PV regions.

In some embodiments, the mechanical resilience and mitigation layer is located above the top-side of the PV regions and provides mechanical resilience to the PV regions against incoming hail or debris; wherein a second mechanical resilience and mitigation layer is a mechanical reinforcement layer that is located beneath the bottom-side of the PV regions and provides additional mechanical reinforcement and mechanical resilience to the PV regions.

In some embodiments, the PV device further comprises: an integrated cooling mechanism, which is an integral part of the PV device, configured to autonomously cool-down the PV regions and to reduce their temperature.

In some embodiments, (i) the mechanical resilience and mitigation layer, and (ii) the integrated cooling mechanism, are two different and/or separate components or layers or regions of the same PV device or solar panel; such that the mechanical resilience and mitigation layer provides mechanical resilience and mitigation but does not provide cooling, and such that the integrated cooling mechanism provides cooling or temperature reduction but does not generally provide mechanical resilience and mitigation.

In some embodiments, the PV device or solar panel may comprise: a top-side encapsulant and/or a top-sheet; and beneath it, the mechanical resilience and mitigation layer; and beneath it, the cooling layer or cooling mechanism; and beneath it, the PV regions; and beneath them, a bottom-side encapsulant and/or a backsheet. In some embodiments, optionally, a bottom-side mechanical resilience and mechanical support layer or component (e.g., an elastomer layer) may be provided beneath the PV regions and above the bottom-side encapsulant and/or a backsheet.

In some embodiments, the PV device or solar panel may comprise: a top-side encapsulant and/or a top-sheet; and beneath it, the cooling layer or cooling mechanism; and beneath it, the mechanical resilience and mitigation layer; and beneath it, the PV regions; and beneath them, a bottom-side encapsulant and/or a backsheet. In some embodiments, optionally, a bottom-side mechanical resilience and mechanical support layer or component (e.g., an elastomer layer) may be provided beneath the PV regions and above the bottom-side encapsulant and/or a backsheet.

In some embodiments, the PV device or solar panel may comprise: a top-side encapsulant and/or a top-sheet; and beneath it, the mechanical resilience and mitigation layer; and beneath it, the PV regions; and beneath them, the cooling layer or cooling mechanism; and beneath it, a bottom-side encapsulant and/or a backsheet. In some embodiments, optionally, a bottom-side mechanical resilience and mechanical support layer or component (e.g., an elastomer layer) may be provided immediately beneath the PV regions and above the cooling mechanism, or may be provided between the cooling mechanism and the bottom-side encapsulant and/or a backsheet.

In some embodiments, the integrated cooling mechanism comprises a Coolant Reservoir that is an integral part of the PV device, wherein the Coolant Reservoir contains a coolant fluid that operates to reduce the temperature of the PV regions.

In some embodiments, the Coolant Reservoir is located above the top-side of the PV regions.

In some embodiments, the Coolant Reservoir is located immediately beneath (and touching from underneath) the bottom-side of the PV regions.

In some embodiments, the Coolant Reservoir is enclosed within an enclosing rim that forms a frame separating the Coolant Reservoir and the PV regions.

In some embodiments, the PV device further comprises: a set of one or more tubes, having an inlet configured to receive the Coolant, and having an outlet configured to output the Coolant; wherein the Coolant continuously circulates within the Coolant Reservoir and the set of one or more tubes; wherein the Coolant has viscosity in a range of 0.5 to 10 centipoise.

In some embodiments, the Coolant is (or includes) air or cold air.

In some embodiments, the Coolant is (or includes) water or cold water or chilled water, or water that were subject to a cooling/chilling process performed externally to the PV device; or water that are pumped directly from a co-located lake or sea or pool or other large body-of-water that operates as a heat exchanger towards the PV device.

In some embodiments, the Coolant is water or cold water; the PV device floats (or is configured to float) on a body-of-water; the Coolant Reservoir obtains water via a first tube from said body-of-water, and outputs water via a second tube into said body-of-water.

In some embodiments, the PV device comprises a pump to actively circulate the Coolant within the tubes and the Coolant Reservoir.

In some embodiments, the PV device comprises a pump (i) to actively circulate the Coolant within the tubes and the Coolant Reservoir, and (ii) to actively collect fresh Coolant from a body-of-coolant on which the PV device is floating.

In some embodiments, the PV device comprises: a heat exchange unit, to cool-down the Coolant as it flows within said tubes; wherein the heat exchange unit surrounds a tube-region of said tubes.

In some embodiments, the PV device comprises: a heat exchange unit, to cool-down the Coolant as it flows within said tubes; wherein the heat exchange unit is located adjacent to a tube-region of said tubes.

In some embodiments, the PV regions comprise: a first set of PV regions, that share a first common Coolant Reservoir located on top of them or beneath them; a second, different, set of PV regions, that share a second, different, common Coolant Reservoir located on top of them or beneath them.

In some embodiments, the first common Coolant Reservoir and the second common Coolant Reservoir are two separate reservoirs; wherein Coolant that flows through the first common Coolant Reservoir does not flow through the second common Coolant Reservoir; wherein Coolant that flows through the second common Coolant Reservoir does not flow through the first common Coolant Reservoir.

In some embodiments, the first common Coolant Reservoir and the second common Coolant Reservoir are fluidly inter-connected; wherein Coolant that flows through the first common Coolant Reservoir also flows subsequently through the second common Coolant Reservoir.

In some embodiments, the PV device comprises: one or more temperature sensors, configured to sense temperature of one of more of the PV regions; and a control unit, configured to dynamically modify a flow-rate of said Coolant through said tubes, based on a temperature value sensed by said one or more temperature sensors.

In some embodiments, the PV device comprises: one or more temperature sensors, configured to sense temperature of one of more of the PV regions; and a control unit, configured to dynamically modify a pumping force of a pumping unit that pumps said Coolant through said tubes, based on a temperature value sensed by said one or more temperature sensors.

In some embodiments, the PV device floats on a body-of-water; wherein the tubes conduct the Coolant in contact with the body-of-water upon which the PV device is floating, and wherein heat generated by the PV regions or near the PV regions is exchanged with the body-of-water.

In some embodiments, at least some of said PV regions are flexible and/or rollable solar cells.

In some embodiments, at least some of said PV regions are flexible and/or rollable solar cells which comprise a single semiconductor wafer having non-transcending craters that penetrate into between 51 to 99 percent of a maximum thickness of said single semiconductor wafer, wherein a thin non-trenched layer of said single semiconductor wafer remains connecting said solar cells; wherein said non-transcending craters contain an elastomer, and dissipate mechanical forces and mechanical shocks that are applied to said solar cells, and enable the solar cells to curve or to bend without becoming functionally damaged.

Some embodiments provide a PV device which comprises, from top to bottom: a top-side encapsulant and top-sheet; beneath them, the mechanical resilience and mitigation layer; beneath it, the PV regions that convert incoming light into electricity; beneath them, and directly touching them from beneath, the cooling mechanism which runs or traverses within the PV device; beneath it, a bottom-side encapsulant and backsheet.

Some embodiments provide a PV device which comprises, from top to bottom: a top-side encapsulant and top-sheet; beneath them, said mechanical resilience and mitigation layer; beneath it, said cooling mechanism which runs or traverses within the PV device; beneath it, said PV regions that convert incoming light into electricity; beneath them, a bottom-side encapsulant and backsheet.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may. Similarly, repeated use of the phrase “in some embodiments” does not necessarily refer to the same set or group of embodiments, although it may.

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

What is claimed is:

1. A photovoltaic (PV) device, comprising:
a plurality of PV regions, configured to generate electricity from incoming light;
wherein the PV regions have: a top-side that is intended to face the incoming light, and a bottom-side that is opposite to said top-side;
a mechanical resilience and mitigation layer, located above the top-side of the PV regions, configured to protect the PV regions from mechanical and functional damage by hail and debris.

2. The PV device according to claim 1,
wherein the mechanical resilience and mitigation layer comprises
a reservoir that contains a liquid.

3. The PV device according to claim 1,
wherein the mechanical resilience and mitigation layer comprises
a reservoir that contains a viscous liquid.

4. The PV device according to claim 1,
wherein the mechanical resilience and mitigation layer comprises
a reservoir that contains a viscous liquid that is transparent.

5. The PV device according to claim 1,
wherein the mechanical resilience and mitigation layer comprises
a reservoir that contains a viscous liquid (I) that is translucent and enables passage therethrough of at least 75 percent of incoming light, and (II) that has viscosity in a range of 2 to 999 centipoise.

6. The PV device according to claim 1,
wherein the mechanical resilience and mitigation layer comprises
a reservoir that contains oil.

7. The PV device according to claim 1,
wherein the mechanical resilience and mitigation layer comprises
a reservoir that contains silicone oil.

8. The PV device according to claim 1,
wherein the reservoir is enclosed within an enclosing rim that forms a frame separating the reservoir and the PV regions.

9. The PV device according to claim 1,
wherein the mechanical resilience and mitigation layer is not stored within a constraining reservoir, but rather, the mechanical resilience and mitigation layer comprises a gel that is surrounding or covering or coating at least the top-side of the PV regions.

10. The PV device according to claim 1,
wherein the mechanical resilience and mitigation layer is not stored within a constraining reservoir, but rather, the mechanical resilience and mitigation layer comprises a partially cross-linked polymer that is surrounding or covering or coating at least the top-side of the PV regions.

11. The PV device according to claim 1,
wherein the mechanical resilience and mitigation layer is located above the top-side of the PV regions and provides mechanical resilience to the PV regions against incoming hail or debris;
wherein a second mechanical resilience and mitigation layer is a mechanical reinforcement layer that is located beneath the bottom-side of the PV regions and provides additional mechanical reinforcement and mechanical resilience to the PV regions.

12. The PV device according to claim 1,
further comprising:
an integrated cooling mechanism, which is an integral part of the PV device,
configured to autonomously cool-down the PV regions and to reduce their temperature.

13. The PV device according to claim 12,
wherein the integrated cooling mechanism comprises a Coolant Reservoir that is an integral part of the PV device, wherein the Coolant Reservoir contains a coolant fluid that operates to reduce the temperature of the PV regions.

14. The PV device according to claim 13,
wherein the Coolant Reservoir is located above the top-side of the PV regions.

15. The PV device according to claim 13,
wherein the Coolant Reservoir is located beneath the bottom-side of the PV regions.

16. The PV device according to claim 13,
wherein the Coolant Reservoir is enclosed within an enclosing rim that forms a frame separating the Coolant Reservoir and the PV regions.

17. The PV device according to claim 13,
further comprising:
a set of one or more tubes, having an inlet configured to receive the Coolant, and having an outlet configured to output the Coolant;
wherein the Coolant continuously circulates within the Coolant Reservoir and the set of one or more tubes;
wherein the Coolant has viscosity in a range of 0.5 to 10 centipoise.

18. The PV device according to claim 13,
wherein the Coolant is air or cold air.

19. The PV device according to claim 13,
wherein the Coolant is water or cold water.

20. The PV device according to claim 13,
wherein the Coolant is water or cold water;
wherein the PV device floats on a body-of-water;
wherein the Coolant Reservoir is connected to tubes that comprise at least a first tube and a second tube,
wherein the Coolant Reservoir obtains water via the first tube from said body-of-water, and outputs water via the second tube into said body-of-water.

21. The PV device according to claim 20,
further comprising a pump that is configured to actively circulate the Coolant within the tubes and the Coolant Reservoir.

22. The PV device according to claim 20,
further comprising a pump that is configured (i) to actively circulate the Coolant within the tubes and the Coolant Reservoir, and (ii) to actively collect fresh Coolant from a body-of-coolant on which the PV device is floating.

23. The PV device according to claim 20, further comprising:
a heat exchange unit, to cool-down the Coolant as it flows within said tubes;
wherein the heat exchange unit surrounds a tube-region of said tubes.

24. The PV device according to claim 20, further comprising:
a heat exchange unit, to cool-down the Coolant as it flows within said tubes;
wherein the heat exchange unit is located adjacent to a tube-region of said tubes.

25. The PV device according to claim 13,
wherein the PV regions comprise:
a first set of PV regions, that share a first common Coolant Reservoir located on top of them or beneath them;
a second, different, set of PV regions, that share a second, different, common Coolant Reservoir located on top of them or beneath them.

26. The PV device according to claim 25,
wherein the first common Coolant Reservoir and the second common Coolant Reservoir are two separate reservoirs,
wherein Coolant that flows through the first common Coolant Reservoir does not flow through the second common Coolant Reservoir,
wherein Coolant that flows through the second common Coolant Reservoir does not flow through the first common Coolant Reservoir.

27. The PV device according to claim 25,
wherein the first common Coolant Reservoir and the second common Coolant Reservoir are fluidly inter-connected,
wherein Coolant that flows through the first common Coolant Reservoir also flows subsequently through the second common Coolant Reservoir.

28. The PV device according to claim 20,
further comprising:
one or more temperature sensors, configured to sense temperature of one of more of the PV regions;
a control unit, configured to dynamically modify a flow-rate of said Coolant through said tubes, based on a temperature value sensed by said one or more temperature sensors.

29. The PV device according to claim 20,
further comprising:
one or more temperature sensors, configured to sense temperature of one of more of the PV regions;
a control unit, configured to dynamically modify a pumping force of a pumping unit that pumps said Coolant through said tubes, based on a temperature value sensed by said one or more temperature sensors.

30. The PV device according to claim 20,
wherein the tubes conduct the Coolant in contact with the body-of-water upon which the PV device is floating, and wherein heat generated by the PV regions or near the PV regions is exchanged with the body-of-water.

31. The PV device according to claim 1,
wherein at least some of said PV regions are flexible and rollable solar cells, that do not break upon flexing or rolling or unrolling.

32. The PV device according to claim 31,
wherein at least some of said PV regions are flexible and rollable solar cells which comprise a single semiconductor wafer having non-transcending craters that penetrate into between 51 to 99 percent of a maximum thickness of said single semiconductor wafer, wherein a thin non-trenched layer of said single semiconductor wafer remains connecting said solar cells; wherein said non-transcending craters contain an elastomer, and dissipate mechanical forces and mechanical shocks that are applied to said solar cells, and enable the solar cells to curve or to bend without becoming functionally damaged.

33. The PV device according to claim 13,
wherein the PV device comprises, from top to bottom:
a top-side encapsulant and top-sheet;
beneath them
said mechanical resilience and mitigation layer;
beneath it,
said PV regions that convert incoming light into electricity;
beneath them,
said cooling mechanism which runs or traverses within the PV device;
beneath it,
a bottom-side encapsulant and backsheet.

34. The PV device according to claim 13,
wherein the PV device comprises, from top to bottom:
a top-side encapsulant and top-sheet;
beneath them
said mechanical resilience and mitigation layer;
beneath it,
said cooling mechanism which runs or traverses within the PV device;
beneath it,
said PV regions that convert incoming light into electricity;
beneath them,
a bottom-side encapsulant and backsheet.
